(19) United States
(12) Patent Application Publication
(10) Pub. No.: US 2012/0118374 A1
(43) Pub. Date: May 17, 2012

(54) PHOTOVOLTAIC DEVICE

(76) Inventor: Seung-Yeop Myong, Seoul (KR)

(21) Appl. No.: 13/326,445

(22) Filed: Dec. 15, 2011

Related U.S. Application Data
(63) Continuation-in-part of application No. 12/762,946, filed on Apr. 19, 2010.

(30) Foreign Application Priority Data
Jul. 3, 2009 (KR) 10-2009-0060742

(51) Int. Cl. H01L 31/0264

(52) U.S. Cl. 136/256

(57) ABSTRACT

Provided is a photovoltaic device that includes: a substrate; a first electrode disposed on the substrate: a photoelectric transformation layer disposed on the first electrode, the photoelectric transformation layer comprising a light absorbing layer which comprises at least one pair of an intrinsic first sub-layer and an intrinsic second sub-layer, each of which comprises a hydrogenated amorphous silicon based material and a hydrogenated proto-crystalline silicon based material having a crystalline silicon grain, and comprises a non-silicon based element; and a second electrode disposed on the photoelectric transformation layer.

### CROSS-REFERENCE TO RELATED APPLICATIONS

This present application is a continuation-in-part application of U.S. patent application Ser. No. 12/762,946 filed on Apr. 19, 2010, which claims priority under 35 U.S.C. §119 to Korean Patent Application No. 10-2009-0060742 filed on Jul. 3, 2009, the entireties of which are hereby incorporated by reference.

### FIELD OF THE INVENTION

This application relates to a photovoltaic device.

### BACKGROUND

Recently, as existing energy sources such as oil and charcoal and so on are expected to be exhausted, attention is now paid to alternative energy sources which can be used in place of the existing energy sources. Among the alternative energy sources, sunlight energy is abundant and has no environmental pollution. For this reason, more and more attention is paid to the sunlight energy.

A photovoltaic device, that is to say, a solar cell converts directly sunlight energy into electrical energy. The photovoltaic device uses mainly photovoltaic effect of semiconductor junction. In other words, when light is incident and absorbed to a semiconductor pin junction formed through a doping process by means of p-type and n-type impurities respectively, light energy generates electrons and holes at the inside of the semiconductor. Then, the electrons and the holes are separated by an internal field so that a photo-electro motive force is generated at both ends of the pin junction. Here, if electrodes are formed at the both ends of junction and connected with wires, an electric current flows externally through the electrodes and the wires.

In order that the existing energy sources such as oil is substituted with the sunlight energy source, it is required that a degradation rate of the photovoltaic device should be low and a stability efficiency of the photovoltaic device should be high, which are produced by the elapse of time.

### SUMMARY OF THE INVENTION

One aspect of this invention includes a photovoltaic device. The photovoltaic device includes: a substrate; a first electrode disposed on the substrate; a photoelectric transformation layer disposed on the first electrode, the photoelectric transformation layer comprising a light absorbing layer which comprises at least one pair of an intrinsic first sub-layer and an intrinsic second sub-layer, each of which comprises a hydrogenated amorphous silicon based material and a hydrogenated proto-crystalline silicon based material having a crystalline silicon grain, and comprises a non-silicon based element; and a second electrode disposed on the photoelectric transformation layer.

Another aspect of this invention includes a photovoltaic device. The photovoltaic device includes: a substrate; a first electrode disposed on the substrate; a photoelectric transformation layer disposed on the first electrode, the photoelectric transformation layer comprising a light absorbing layer which comprises at least one pair of an intrinsic first sub-layer and an intrinsic second sub-layer, each of which comprises hydrogenated micro-crystalline silicon germanium and hydrogenated micro-crystalline silicon; and a second electrode disposed on the photoelectric transformation layer.

The light absorbing layer may be divided into a first area and a second area, the first area is constituted by the at least one pair of the first sub-layer and the second sub-layer, and the second area is constituted by a single layer.

### BRIEF DESCRIPTION OF THE DRAWINGS

The embodiment will be described in detail with reference to the following drawings.

FIG. 1 shows a photovoltaic device according to a first embodiment of the present invention.

FIG. 2 shows another photovoltaic device according to a second embodiment of the present invention.

FIGS. 3A to 3H show a manufacturing method of a photovoltaic device according to an embodiment of the present invention.

FIG. 4 shows a plasma-enhanced chemical vapor deposition apparatus for forming a light absorbing layer according to an embodiment of the present invention.

FIGS. 5A to 5B show a variation of flow rate of source gas for forming a light absorbing layer according to an embodiment of the present invention

FIGS. 6A to 6B show another variation of flow rate of source gas for forming a light absorbing layer according to an embodiment of the present invention.

FIGS. 7A to 7B show further another variation of flow rate of source gas for forming a light absorbing layer according to an embodiment of the present invention.

FIG. 8 shows a light absorbing layer including a plurality of sub-layers included in an embodiment of the present invention.

FIG. 9 shows a light absorbing layer including a hydrogenated proto-crystalline silicon single layer according to an embodiment of the present invention.

### DETAILED DESCRIPTION

Embodiments will be described in a more detailed manner with reference to the drawings.

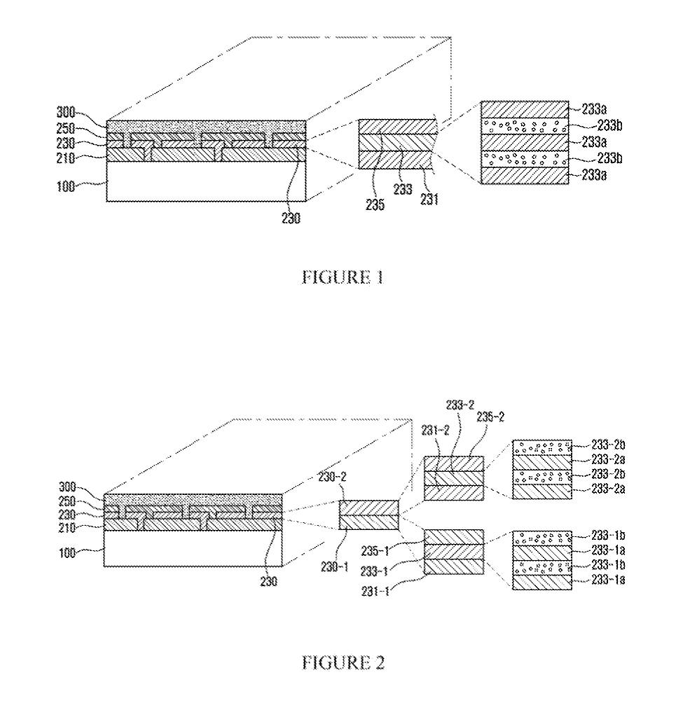

FIG. 1 shows a photovoltaic device according to a first embodiment of the present invention. As shown, a photovoltaic device includes a substrate 100, a first electrode 210, a second electrode 250, a photoelectric transformation layer 230 and a protecting layer 300.

In detail, the first electrodes 210 are disposed on the substrate 100. The first electrodes 210 are spaced from each other at a regular interval in such a manner that adjacent first electrodes are not electrically short-circuited. The photoelectric transformation layer 230 is disposed on the first electrode 210 in such a manner as to cover the area spaced between the first electrodes at a regular interval. The second electrodes 250 are disposed on the photoelectric transformation layer 230 and spaced from each other at a regular interval in such a manner that adjacent second electrodes are not electrically short-circuited. In this case, the second electrode 250 penetrates the photoelectric transformation layer and is electrically connected to the first electrode 210 such that the second electrode 250 is connected in series to the first electrode 210. The adjacent photoelectric transformation layers 230 are spaced at the same interval as the interval between the second electrodes. The protecting layer 300 is disposed on the second electrode in such a manner as to cover the area spaced between the second electrodes and the area spaced between the photoelectric transformation layers.

The photoelectric transformation layer 230 includes a p-type semiconductor layer 231, a light absorbing layer 233 and an n-type semiconductor layer 235. The light absorbing layer 233 includes at least one pair of an intrinsic first sub-layer 233A and an intrinsic second sub-layer 233B. The first sub-layer 233A includes a hydrogenated amorphous silicon based material. The second sub-layer 233B includes a hydrogenated proto-crystalline silicon based material. The first sub-layer 233A and the second sub-layer 233B also include a non-silicon based element. The second sub-layer 233B includes a crystalline silicon grain surrounded by the hydrogenated amorphous silicon based material. Even though it is shown in FIG. 1 that the entire light absorbing layer 233 has a structure in which the first sub-layer 233A and second sub-layer 233B are alternately stacked, it is just an example of the present invention. A light absorbing layer 233 according to an embodiment of the present invention may include a first area in which the first sub-layer 233A and second sub-layer 233B are alternately stacked, and a second area other than the first area. Here, the second area may not have a structure in which the first sub-layer 233A and the second sub-layer 233B are alternately stacked and have a single layer. The second area may include hydrogenated amorphous silicon, or a hydrogenated amorphous silicon based material which comprises relatively small amount of the non-silicon based element. The first area may be disposed to contact with the p-type semiconductor layer 231 and the second area may be disposed to contact with the n-type semiconductor layer 235. It is possible to dispose the first area between the second areas each of which contacting the p-type semiconductor layer 231 and n-type semiconductor layer 235. It is also possible to dispose the first area to contact with the n-type semiconductor layer 235 and to dispose the second area under the first area to contact with the p-type semiconductor layer 231. The degradation rate of a photovoltaic device can be lowered through effectively reducing the recombination loss at a p/i interface by placing the first area closer to the p-type semiconductor layer 231.

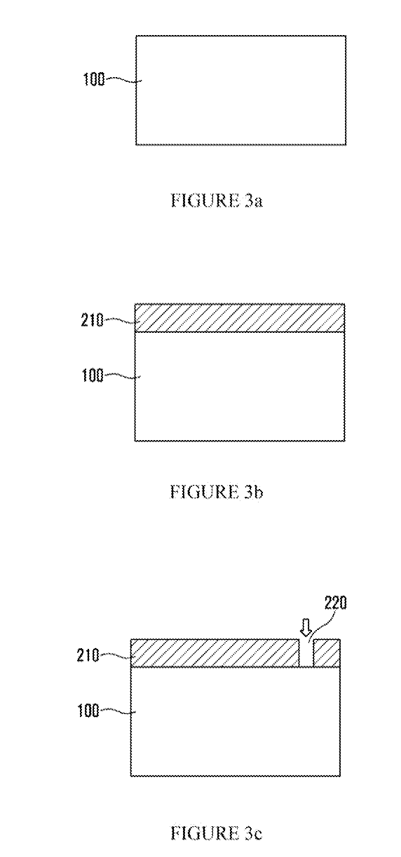

FIG. 2 shows another photovoltaic device according to a second embodiment of the present invention. Since a photovoltaic device of FIG. 2 is almost similar to that of FIG. 1, descriptions of the same structure will be omitted. In FIG. 2, the photoelectric transformation layer 230 includes a first photoelectric transformation layer 230-1 and a second photoelectric transformation layer 230-2 disposed on the first photoelectric transformation layer. The first photoelectric transformation layer and the second photoelectric transformation layer include a p-type semiconductor layer 231-1 and 231-2, light absorbing layer 233-1 and 233-2 and n-type semiconductor layer 235-1 and 235-2.

The light absorbing layer 233-1 and 233-2 include first sub-layer 233-1A and 233-2A and second sub-layer 233-1B and 233-2B stacked on the first sub-layer. Here, the light absorbing layer 233-1 included in the first photoelectric transformation layer 230-1 includes the intrinsic first sub-layer 233-1A and the intrinsic second sub-layer 233-1B. The first sub-layer 233-1A includes a hydrogenated amorphous silicon based material and the second sub-layer 233-1B includes the hydrogenated proto-crystalline silicon based material. The light absorbing layer 233-2 included in the second photoelectric transformation layer 230-2 includes the first sub-layer 233-2A and the second sub-layer 233-2B. The first sub-layer 233-2A includes hydrogenated micro-crystalline silicon germanium and the second sub-layer 233-2B includes hydrogenated micro-crystalline silicon.

While only two photoelectric transformation layers are provided in the present embodiment, three or more photoelectric transformation layers can be also provided. Regarding a second photoelectric transformation layer or a third photoelectric transformation layer among three photoelectric transformation layers, which is far from a side of incident light, the second photoelectric transformation layer or the third photoelectric transformation layer can include a light absorbing layer including a first sub-layer and a second sub-layer. The first sub-layer includes hydrogenated micro-crystalline silicon germanium and the second sub-layer includes hydrogenated micro-crystalline silicon.

With respect to such photovoltaic devices according to the first and the second embodiments, a manufacturing method of the photovoltaic device will be described below in more detail.

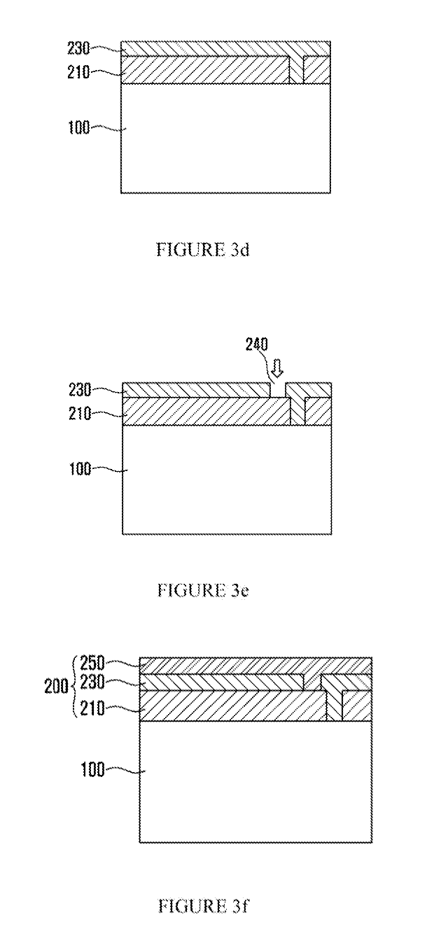

FIGS. 3A to 3H show a manufacturing method of a photovoltaic device according to an embodiment of the present invention.

As shown in FIG. 3A, a substrate 100 is provided first. An insulating transparent substrate 100 can be used as the substrate 100.

As shown in FIG. 3B, a first electrode 210 is formed on the substrate 100. In the embodiment of the present invention, the first electrode 210 can be made by chemical vapor deposition (CVD) or sputtering. The first electrode 210 can be made of transparent conductive oxide (TCO) such as SnO₂ or ZnO.

As shown in FIG. 3C, a laser beam is irradiated onto the first electrode 210 or the substrate 100 so that the first electrode 210 is partially removed. As a result, a first separation groove 220 is formed. That is, since the separation groove 210 penetrates the first electrode 210, preventing adjacent first electrodes from being short-circuited.

As shown in FIG. 3D, at least one photoelectric transformation layer 230 including a light absorbing layer is stacked by CVD in such a manner as to cover the first electrode 210 and the first separation groove 220. In this case, each photoelectric transformation layer 230 includes a p-type semiconductor layer, a light absorbing layer and an n-type semiconductor layer. In order to form the p-type semiconductor layer, source gas including silicon, for example, SiH₄ and source gas including group 3 elements, for example, B₂H₆ are mixed in a reaction chamber, and then the p-type semiconductor layer is formed by PECVD (Plasma Enhanced Chemical Vapor Deposition). Then, the source gas including silicon is flown to the reaction chamber so that the light absorbing layer is formed on the p-type semiconductor layer by PECVD. A method of manufacturing the light absorbing layer will be described later in detail. Finally, reaction gas including group 5 element, for example, PH₃ and source gas including silicon are mixed, and then the n-type semiconductor layer is stacked on an intrinsic semiconductor by PECVD. Accordingly, the p-type semiconductor layer, the light absorbing layer and the n-type semiconductor layer are stacked on the first electrode 210 in order specified.

The light absorbing layer according to the embodiment of the present invention can be included in a single junction photovoltaic device including one photoelectric transformation layer 230 or in a multiple junction photovoltaic device including a plurality of photoelectric transformation layers.

As shown in FIG. 3E, a laser beam is irradiated from the air onto the substrate 100 or the photoelectric transformation layer 230 so that the photoelectric transformation layer 230 is partially removed. A second separation groove 240 is hereby formed in the photoelectric transformation layer 230.

As shown in FIG. 3F, the second electrode 250 is formed by CVD or sputtering process to cover the photoelectric transformation layer 230 and the second separation groove 240. A metal layer made of Al or Ag can be used as the second electrode 250. Also, the second electrode 250 may be made of transparent conductive oxide (TCO) such as ZnO, SnO₂ or ITO formed by CVD or sputtering.

As shown in FIG. 3G, a laser beam is irradiated from the air onto the substrate 100 so that the photoelectric transformation layer 230 and the second electrode 250 are partially removed. As a result, a third separation groove 270 is formed in the photo voltaic layer 230 and the second electrode 250.

As shown in FIG. 3H, through lamination process, a protecting layer 300 covers partially or entirely a photovoltaic cell 200 including the photoelectric transformation layer 230, the first electrode 210 and the second electrode 250 so as to protect the photovoltaic cell 200. The protecting layer 300 can include encapsulant such as ethylene Vinyl Acetate (EVA) or Poly Vinyl Butiral (PVB).

Through such a process, provided is the photoelectric transformation layer 200 having the protecting layer 300 formed thereon. A backsheet or back glass (not shown) can be made on the protecting layer.

In the next place, a manufacturing method of the light absorbing layer will be described in detail with reference to figures.

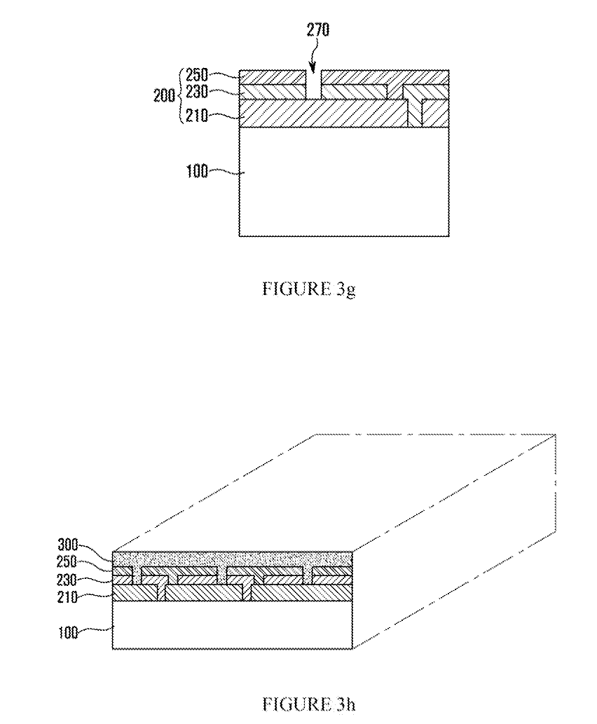

FIG. 4 shows a plasma-enhanced chemical vapor deposition apparatus for forming a light absorbing layer according to an embodiment of the present invention. As shown in FIG. 4, the first electrode 210, the p-type semiconductor layer 231 or the n-type semiconductor layer 235 are formed on the substrate 100. The substrate 100 is disposed on a plate 300 functioning as an electrode. A vacuum pump 320 operates in order to remove impurities in a chamber 310 before the light absorbing layer forming process. As a result, the impurities in the chamber 310 are removed through an angle valve 330 so that the inside of the chamber 310 is actually in a vacuum state.

When the inside of the chamber 310 is actually in a vacuum state, source gas such as hydrogen (H₂) and silane (SiH₄) and source gas including non-silicon based element are flown to the inside of the chamber 310 through mass flow controllers MFC1, MFC2 and MFC3 and an electrode 340 having a nozzle formed therein.

In other words, the hydrogen can be flown to the chamber through a first mass flow controller MFC1. The silane can he flown to the chamber through a second mass flow controller MFC2. The non-silicon based element such as carbon, oxygen or germanium can be flown to the chamber through a third mass flow controller MFC3.

Here, the angle valve 330 is controlled to maintain the pressure of the chamber 310 constant. When the pressure of the chamber 310 is maintained constant, silicon powder caused by turbulence created in the chamber 310 can be prevented from being generated and deposition condition can be maintained constant. The hydrogen is flown to the chamber in order to dilute the silane and reduces Staebler-Wronski effect.

When the source gases are flown to the chamber and a voltage from an electric power source E is supplied to the electrode, an electric potential difference is generated between the electrode 340 and the plate 300. As a result, the source gas is in a plasma state, and the light absorbing layer is deposited on the p-type semiconductor layer 231 or the n-type semiconductor layer 235.

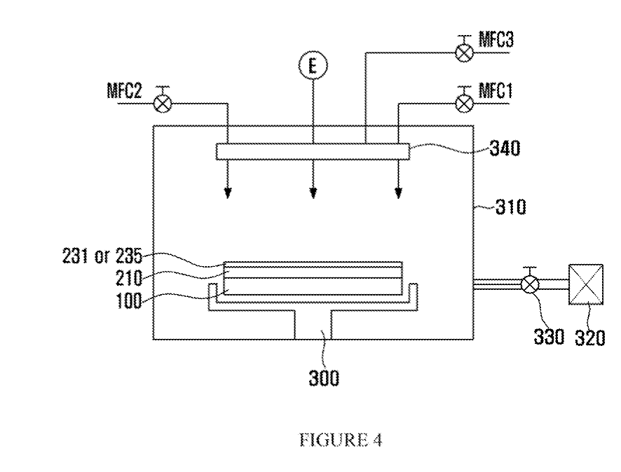

FIGS. 5A to 5B show a variation of flow rate of source gas for forming a light absorbing layer according to an embodiment of the present invention.

As shown in FIG. 5A, a flow rate A of hydrogen and a flow rate B of silane are constant in accordance with the elapsed deposition time T. A flow rate of the source gas including the non-silicon based element such as oxygen or carbon varies alternately within a range between a first flow rate value α and a second flow rate value β in accordance with the elapsed deposition time T. The first flow rate value α and the second flow rate value β are reduced in accordance with the elapsed deposition time T.

As shown in FIG. 5B, the flow rate A of hydrogen and the flow rate B of silane are constant in accordance with the elapsed deposition time T. The flow rate of the source gas including the non-silicon based element such as germanium varies alternately within a range between the first flow rate value α and the second flow rate value β in accordance with the elapsed deposition time T. The first flow rate value α and the second flow rate value β are increased in accordance with the elapsed deposition time T. In this case, as shown in FIGS. 5A and 5B, during one cycle P derived from a sum of a duration time of the first flow rate value α and a duration time of the second flow rate value β, the duration time t1 of the first flow rate value α and the duration time t2 of the second flow rate value β are constant in accordance with the elapsed deposition time T.

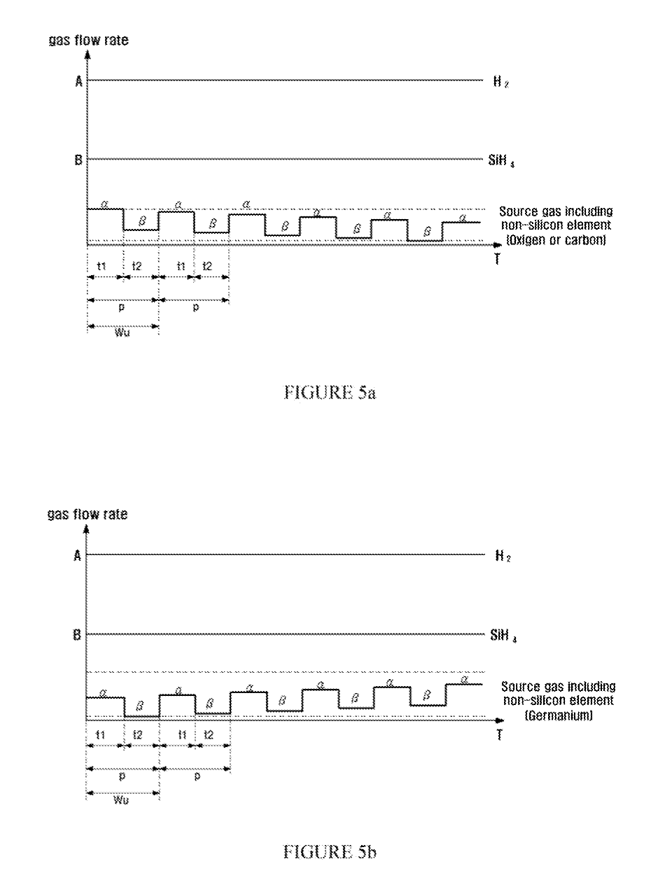

FIGS. 6A to 6B show another variation of flow rate of source gas for forming a light absorbing layer according to an embodiment of the present invention.

As shown in FIG. 6A, the flow rate A of hydrogen and the flow rate B of silane are constant in accordance with the elapsed deposition time T. The flow rate of the source gas including the non-silicon based element such as oxygen or carbon varies alternately within a range between the first flow rate value α and the second flow rate value β in accordance with the elapsed deposition time T. During one cycle P derived from a sum of a duration time of the first flow rate value α and a duration time of the second flow rate value β, the duration time t1 of the first flow rate value α and the duration time t2 of the second flow rate value β are reduced in accordance with the elapsed deposition time T.

100501 As shown in FIG. 6B, the flow rate A of hydrogen and the flow rate B of silane are constant in accordance with the elapsed deposition time T. The flow rate of the source gas including the non-silicon based element such as germanium varies alternately within a range between the first flow rate value α and the second flow rate value β in accordance with the elapse of deposition time T. During one cycle P derived from a sum of a duration time of the first flow rate value α and a duration time of the second flow rate value β, the duration time t1 of the first flow rate value α and the duration time t2 of the second flow rate value β are increased in accordance with the elapsed deposition time T.

Here, as shown in FIGS. 6A and 6B, the first flow rate value α and the second flow rate value β are constant in accordance with the elapsed deposition time T. During one cycle P derived from a sum of a duration time of the first flow rate value α and a duration time of the second flow rate value β, a ratio of the duration time t1 of the first flow rate value α to the duration time t2 of the second flow rate value β is constant in accordance with the elapsed deposition time T.

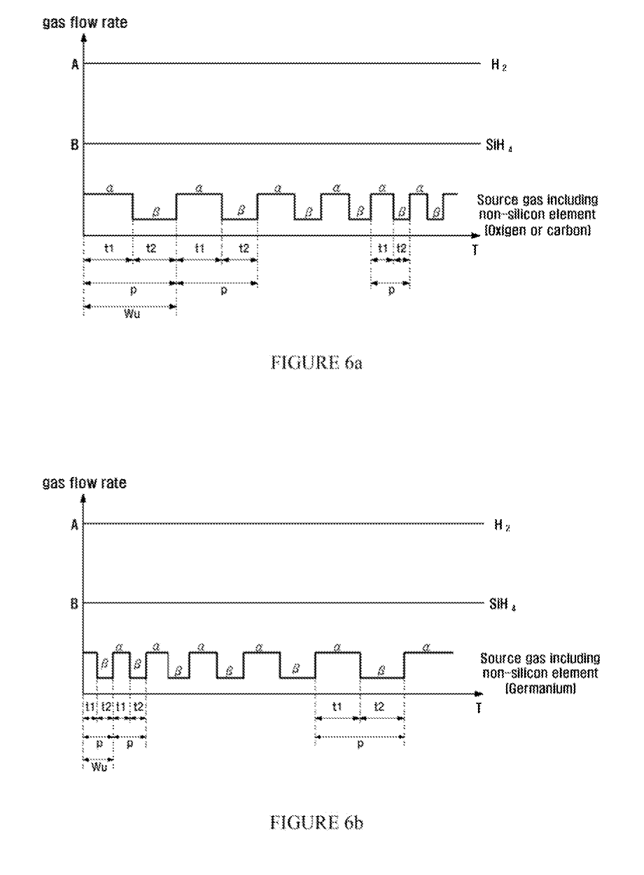

FIGS. 7A to 7B show further another variation of flow rate of source gas for forming a light absorbing layer according to an embodiment of the present invention.

As shown in FIG. 7A, the flow rate A of hydrogen and the flow rate B of silane are constant in accordance with the elapsed deposition time T. The flow rate of the source gas including the non-silicon based element such as oxygen or carbon varies alternately within a range between the first flow rate value α and the second flow rate value β in accordance with the elapsed deposition time T. In this case, during one cycle P derived from a sum of a duration time of the first flow rate value α and a duration time of the second flow rate value β, the duration time t1 of the first flow rate value α and the duration time t2 of the second flow rate value β are reduced in accordance with the elapsed deposition time T. The first flow rate value α and the second flow rate value β are reduced in accordance with the elapsed deposition time T.

As shown in FIG. 7B, the flow rate A of hydrogen and the flow rate B of silane are constant in accordance with the elapsed deposition time T. The flow rate of the source gas including the non-silicon based element such as germanium varies alternately within a range between the first flow rate value α and the second flow rate value β in accordance with the elapsed deposition time T. In this case, during one cycle P derived from a sum of a duration time of the first flow rate value α and a duration time of the second flow rate value β, the duration time t1 of the first flow rate value α and the duration time t2 of the second flow rate value β are increased in accordance with the elapsed deposition time T. The first flow rate value α and the second flow rate value β are increased in accordance with the elapsed deposition time T.

In this case, During one cycle P derived from a sum of a duration time of the first flow rate value α and a duration time of the second flow rate value β, a ratio of the duration time t1 of the first flow rate value α to the duration time t2 of the second flow rate value β is constant in accordance with the elapsed deposition time T.

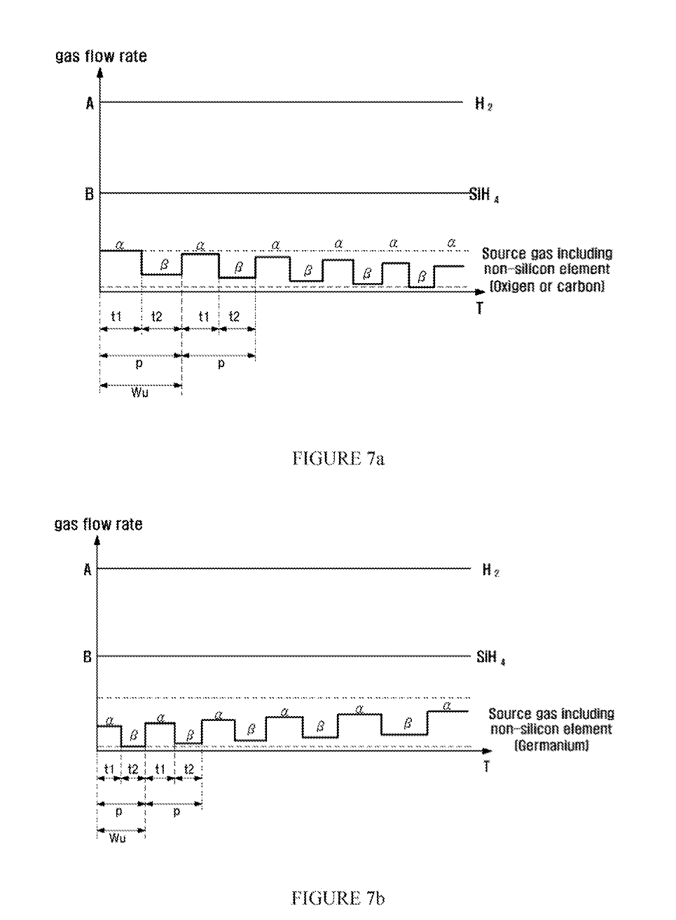

As described with reference to FIGS. 5A to 7B, in the embodiments of the present invention, the flow rate A of hydrogen and the flow rate B of silane are constant in accordance with the elapsed deposition time T. Additionally, with respect to the source gas including non-silicon based element, a ratio of a duration time t1 of the first flow rate value α to a duration time t2 of the second flow rate value β is constant as well. As a result, the first sub-layer 233A and the second sub-layer 233B of FIG. 8 are formed, which have a certain thickness ratio there between.

In this case, the flow rate of the source gas including non-silicon based element decreases or increases, varying alternately within a range between the first flow rate value α and the second flow rate value β in accordance with the elapsed deposition time T. This will be described later in detail.

As such, the flow rate A of hydrogen and the flow rate B of silane are constant in accordance with the elapsed deposition time T. The flow rate of the source gas including non-silicon based element varies alternately within a range between the first flow rate α and the second flow rate β. Therefore, a hydrogen dilution ratio, that is, a ratio of the flow rate of the silane to the flow rate of the hydrogen, is constant.

In addition, if the flow rate of the source gas including non-silicon based element varies, as shown in FIG. 8, a light absorbing layer including a plurality of sub-layers 233A and 233B is made on the p-type semiconductor layer 231 or the n-type semiconductor layer 235. The sub-layer 233A is a hydrogenated amorphous silicon based sub-layer (a-Si:H) including an amorphous silicon based element. The sub-layer 233B is a hydrogenated proto-crystalline silicon based sub-layer (pc-Si:H) including crystalline silicon grains. The hydrogenated proto-crystalline silicon based sub-layer 233B is produced during the process of a phase change of the amorphous silicon into micro-crystalline silicon. Hereinafter, the hydrogenated amorphous silicon based sub-layer is referred to as the first sub-layer 233A. The hydrogenated proto-crystalline silicon based sub-layer is referred to as the second sub-layer 233B. The hydrogenated proto-crystalline silicon has a structure in which crystalline silicon grains (3 to 10 nm in diameter) are embedded in amorphous silicon matrix. Thus, components of crystal silicon are not detected by XRD (X-Ray Diffraction) or Raman Spectroscopy on the hydrogenated proto-crystalline silicon. However, crystalline silicon grains can be detected from HRTEM (High Resolution Transmission Electron Microscopy) images of the hydrogenated proto-crystalline silicon.

The higher the flow rate of the source gas including non-silicon based element increases, the lower the crystalline and a deposition rate are. The lower the flow rate of the source gas including non-silicon based element decreases, the higher the crystalline and a deposition rate are. Therefore, as shown in FIGS. 5A to 7B, the first sub-layer 233A of which deposition speed is relatively low is formed during the duration time t1 of the flow rate value α of the source gas including non-silicon based element. The second sub-layer 233B of which deposition speed is relatively high is formed during the duration time t2 of the flow rate value β of the source gas including non-silicon based element.

100611 Therefore, when the source gas including the non-silicon based element such as oxygen is supplied to the chamber, the first sub-layer 233A and the second sub-layer 233B include hydrogenated amorphous silicon oxide (i-a-SiO:H). The second sub-layer 233B includes a crystalline silicon grain surrounded by the hydrogenated amorphous silicon oxide (i-a-SiO:H).

When the source gas including the non-silicon based element such as carbon is supplied to the chamber, the first sub-layer 233A and the second sub-layer 233B include hydrogenated amorphous silicon carbide (i-a-SiC:H). The second sub-layer 233B includes a crystalline silicon grain surrounded by the hydrogenated amorphous silicon carbide (i-a-SiC:H).

When the source gas including the non-silicon based element such as germanium is supplied to the chamber, the first sub-layer 233A and the second sub-layer 233B include hydrogenated amorphous silicon germanium (i-a-SiGe:H). The second sub-layer 233B includes a crystalline silicon grain surrounded by the hydrogenated amorphous silicon germanium (i-a-SiGe:H).

Here, as shown in FIGS. 5A to 7B, unless the source gas including non-silicon based element is supplied to the chamber during the time t2, that is, the second flow rate value β is equal to 0, the second sub-layer 233B includes a crystalline silicon grain surrounded by the hydrogenated amorphous silicon (i-a-Si:H).

In this case, the diameter of the crystalline silicon grain can be equal to or more than 3 nm and equal to or less than 10 nm. If the crystalline silicon grain has a diameter less than 3 nm, it is difficult to form the crystalline silicon grain and a degradation rate reduction effect of a solar cell is reduced. If the crystalline silicon grain has a diameter greater than 10 nm, the volume of grain boundary in the circumference of the crystalline silicon grain is excessively increased. As a result, the crystalline silicon grain is also increasingly recombined with each other, thereby reducing the efficiency.

As such, when the light absorbing layer 233 including a plurality of the sub-layers 233A and 233B is made, the degradation rate, i.e., a value which is obtained by dividing a difference between initial efficiency and stabilization efficiency by the initial efficiency, is reduced. Accordingly, the photovoltaic device according to the embodiment of the present invention can have high stabilization efficiency.

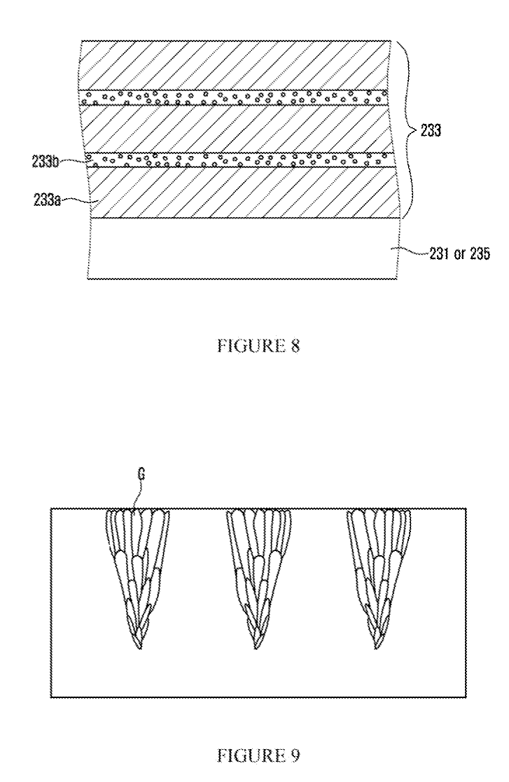

In other words, the first sub-layer 233A made of an amorphous silicon based material interrupts columnar growth of the crystalline silicon grain of the second sub-layer 233B. As shown in FIG. 9, when the light absorbing layer is formed of only a proto-crystalline silicon single layer unlike the embodiment of the present invention, the columnar growth of the crystalline silicon grain is accomplished. That is to say, as deposition is performed, the diameter of the crystalline silicon grain G is increased.

Such a columnar growth of the crystalline silicon grain increases a recombination rate of carriers such as an electron hole and an electron at a grain boundary, thus the initial efficiency of a photovoltaic device is lowered.

However, in the case of the light absorbing layer 233 including a plurality of sub-layers 233A and 233B in the embodiment of the present invention, since a short-range-order (SRO) and a medium-range-order (MRO) in the silicon thin film matrix are improved, the degradation rate of the light absorbing layer 233 is lowered and the stabilization efficiency is increased. The amorphous silicon based material of the first sub-layer 233A interrupts the columnar growth of the crystalline silicon grain in the second sub-layer 233B, thereby reducing a diameter variation of the crystalline silicon grain. As a result, a time required for the efficiency of the photovoltaic device to reach the stabilization efficiency is reduced and high stabilization efficiency is obtained.

The crystalline silicon grains of the second sub-layer 233B are covered with amorphous silicon based material and isolated from each other. The isolated crystalline silicon grains act as radiative recombination centers of some of the captured carriers, and hence suppress photocreation of dangling bonds. As a result, the non-radiative recombination in the amorphous silicon based material, which surrounds the crystalline silicon grains of the second sub-layer 233B, is reduced.

Meanwhile, as shown in FIGS. 5A, 6A and 7A, in accordance with the elapsed deposition time T, reduced are the first flow rate value α and the second flow rate value β of the source gas including non-silicon based element such as oxygen or carbon, or reduced are a duration time t1 of the first flow rate value α and a duration time t2 of the second flow rate value β. In FIGS. 5A, 6A and 7A, while all of the first flow rate value α and the second flow rate value β are reduced, at least one of the values α and β can be reduced. Also, all of the duration time t1 of the first flow rate value α and the duration time t2 of the second flow rate value β can be reduced. At least one of the duration times of t1 and t2 can be also reduced. The first sub-layers 233A and the second sub-layers 233B, which are formed in accordance with the first flow rate value α and the second flow rate value β, of the light absorbing layer 233 are formed far from a side of incident light. Therefore, the farther the first and the second sub-layers 233a and 233B are from a side of incident light, the smaller the optical band gap of the first and the second sub-layers 233a and 233B gradually are.

Light with a short wavelength having a high energy density has a small penetration depth. A larger optical band gap is required to absorb light with a particular wavelength having a high energy density. Therefore, the closer the sub-layers 233A and 233B are to a side of incident light, the relatively larger optical band gap the sub-layers 223A and 233B have. As a result, light with a particular wavelength having a high energy density is absorbed as much as possible. The farther the sub-layers 233A and 233B are from a side of incident light, the relatively smaller optical band gap the sub-layers 233A and 233B have. As a result, light with a wavelength other than the particular wavelength mentioned above is absorbed as much as possible.

Here, the more the flow rate of the source gas including non-silicon based element such as oxygen or carbon is increased, the larger the optical band gap is. Therefore, in accordance with the elapsed deposition time T, reduced are the first flow rate value α and the second flow rate value β of the source gas including non-silicon based element such as oxygen or carbon, or reduced are a duration time t1 of the first flow rate value α and a duration time t2 of the second flow rate value β.

In addition, as shown in FIGS. 5B, 6B and 7B, in accordance with the elapsed deposition time T, increased are the first flow rate value α and the second flow rate value β of the source gas including non-silicon based element such as germanium, or increased are a duration time t1 of the first flow rate value α and a duration time t2 of the second flow rate value β. In FIGS. 5B, 6B and 7B, while all of the first flow rate value α and the second flow rate value β are increased, at least one of the values α and β can be increased. Also, all of the duration time t I of the first flow rate value α and the duration time t2 of the second flow rate value β can be increased. At least one of the duration times of t1 and t2 can be also increased. The first sub-layers 233A and the second sub-layers 233B, which are formed in accordance with the first flow rate value α and the second flow rate value β, of the light absorbing layer 233 are formed far from a side of incident light. Therefore, the farther the first and the second sub-layers 233a and 233B are from a side of incident light, the smaller the optical band gap of the first and the second sub-layers 233a and 233B gradually are.

In this case, the more the flow rate of the source gas including non-silicon based element such as germanium is increased, the smaller the optical band gap is. Therefore, in accordance with the elapsed deposition time T, increased are the first flow rate value α and the second flow rate value β of the source gas including non-silicon based element such as germanium, or reduced are a duration time t1 of the first flow rate value α and a duration time t2 of the second flow rate value β.

As described above light with a particular wavelength having a high energy density has a small penetration depth. A larger optical band gap is required to absorb light with a particular wavelength having a high energy density.

Therefore, the lower flow rate the source gas including non-silicon based element such as germanium has, the relatively larger optical band gap the sub-layers 233A and 233B closer to a side of incident light have. As a result, the sub-layers 233A and 233B closer to a side of incident light absorb light with a particular wavelength as much as possible.

Also, the larger flow rate the source gas including non-silicon based element such as germanium has, the relatively smaller optical band gap the sub-layers 233A and 233B farther from a side of incident light have. As a result, the sub-layers 233A and 23313 farther from a side of incident light absorb light with a wavelength other than the particular wavelength mentioned above as much as possible.

In the mean time, as described above, the hydrogen dilution ratio and the pressure in the chamber 310 in the embodiment of the present invention are constant. Since a flow rates of hydrogen and silane supplied to the inside of the chamber 310 are larger than the flow rate of the source gas including non-silicon based element, it is relatively more difficult to control the flow rates of hydrogen and silane than to control the flow rate of the source gas including non-silicon based element, and turbulence can be generated in the chamber 310 due to the flows of hydrogen and silane. Accordingly, if the flow rates of the hydrogen and the silane are constant, it is easy to control the source gas including non-silicon based element having low flow rates and possible to reduce the possibility of generating turbulency within the chamber 310, thereby improving a film quality of the light absorbing layer 233.

If the flow rate of hydrogen varies within a range between 0 and a certain value so as to form the first sub-layer 233A and the second sub-layer 233B, during a period of time during which the flow rate of hydrogen is equal to 0 as the flow rate of hydrogen varies cyclically, that is, a period of time during which hydrogen is not flown from the outside to the chamber, the hydrogen which remains in the chamber 310 increases in accordance with deposition time T, increasing crystallinity of the sub-layers. As a result, it is difficult to form sub-layers having a uniform crystal size and a uniform thickness.

On the other hand, in the embodiment of the present invention, since the flow rates of hydrogen and silane are constant and the flow rate of the source gas including non-silicon based element varies cyclically, an amount of hydrogen in the chamber 310 is maintained constant, making it easier to form the sub-layers 233A and 233B having a uniform crystal size and a uniform thickness.

As described above, in the embodiments of the present invention, plasma-enhanced chemical vapor deposition method is used instead of photo-CVD. The photo-CVD is not suitable for manufacturing a large area photovoltaic device. Also, as deposition is performed, a thin film is deposited on a quartz window of a photo-CVD device, reducing UV light penetrating through the quartz window.

For this reason, a deposition rate is gradually reduced and the thicknesses of the first sub-layer 233A and the second sub-layer 233B are gradually reduced. Contrarily, the plasma-enhanced chemical vapor deposition (PECVD) method can solve the shortcomings of the photo-CVD.

In the plasma-enhanced chemical vapor deposition method used in the embodiment of the present invention, a frequency of a voltage supplied from an electric power source E can be equal to or more than 13.56 MHz. When a frequency of a voltage supplied from an electric power source E is equal to or more than 27.12 MHz, a deposition rate is improved and a quantum dot caused by a crystalline silicon grain can be easily formed.

As mentioned above, the crystalline silicon grain having a uniform diameter reduces a time required for the efficiency of the photovoltaic device to reach the stabilization efficiency and improves the stabilization efficiency. To this end, in the embodiment of the present invention, the hydrogen dilution ratio of the chamber 310 is maintained constant while the second sub-layer 233B of the light absorbing layer 233 is repeatedly deposited. In other words, the hydrogen dilution ratio (within an allowable error range) of the second sub-layer 233B is maintained constant in every period that the first and second sub-layers 233A and 23313 are formed.

Even though it is explained referring to FIG. 5 to FIG. 8 that the entire light absorbing layer 233 has a structure in which the first sub-layer 233A and second sub-layer 233B are alternately stacked, it is just an example of the present invention. A light absorbing layer 233 according to an embodiment of the present invention may include a first area of at least one pair of the first sub-layer 233A and second sub-layer 233B and a second area other than the first area. Here, the second area may not have a structure in which the first sub-layer 233A and the second sub-layer 233B are alternately stacked and have a single layer. The second area may include hydrogenated amorphous silicon, or a hydrogenated amorphous silicon based material which comprises relatively small amount of the non-silicon based element. The description explained referring to FIG. 5 to FIG. 8 can be applied to form the first area in which the first sub-layer 233A and the second sub-layer 233B are alternately stacked.

By forming the light absorbing layer 233 as mentioned above, not only the high stabilization efficiency of a photovoltaic device but also short time and low cost for manufacturing thereof can be obtained. That is, the time and cost required for manufacturing the light absorbing layer 233 can be reduced by forming the light absorbing layer 233 including the second area of the hydrogenated amorphous silicon single layer or the hydrogenated amorphous silicon based material. Furthermore, the high stabilization efficiency can be obtained due to the lowered degradation rate by forming the light absorbing layer 233 including the first area of the First sub-layer 233A and the second sub-layer 233B alternately stacked.

Hereinafter, a light absorbing layer 233 refers to not only a case that the first sub-layer 233A and second sub-layer 233B are alternately stacked in the entire light absorbing layer 233 but also a case that the first sub-layer 233A and second sub-layer 233B are alternately stacked only in a part of the light absorbing layer 233.

When oxygen or carbon as a source gas including non-silicon based element is flown to the chamber 310, the thickness of the light absorbing layer 233 is equal to or more than 150 nm and is equal to or less than 300 nm. An average oxygen content of the light absorbing layer 233 can be equal to or more than 0 atomic % and is equal to or less than 3 atomic %. An optical band gap of the light absorbing layer 233 can be equal to or more than 1.85 eV and is equal to or less than 2.1 eV.

If the optical band gap of the light absorbing layer 233 formed by a flow of oxygen or carbon is equal to or more than 1.85 eV, the light absorbing layer 233 can absorb a lot of light with a short wavelength having a high energy density. If the optical band gap of the light absorbing layer 233 is greater than 2.1 eV, the light absorbing layer 233 including the plurality of sub-layers 233A and 233B is difficult to form and absorption of light is reduced. Therefore, the efficiency can be reduced by reduction of a short-circuit current.

When an average oxygen content or an average carbon content of the light absorbing layer 233 formed by a flow of oxygen or carbon is greater than 3 atomic %, the optical band gap of the light absorbing layer 233 is rapidly increased and a dangling bond density is suddenly increased. As a result, the short-circuit current and a fill factor (FF) are reduced, so that the efficiency is degraded.

Thus, the light absorbing layer 233 formed by a flow of oxygen or carbon can be included in a top cell of a multiple junction photovoltaic device so as to absorb a lot of light with a short wavelength. The top cell corresponds to a photoelectric transformation layer on which light is first incident, among a plurality of photoelectric transformation layers 230.

When germanium as a source gas including non-silicon based element is flown to the chamber 310, the thickness of the light absorbing layer 233 is equal to or more than 300 nm and is equal to or less than 1000 nm. An average germanium content of the light absorbing layer 233 can be equal to or more than 0 atomic % and is equal to or less than 20 atomic %. An optical band gap of the light absorbing layer 233 can be equal to or more than 1.3 eV and is equal to or less than 1.7 eV. If the optical band gap of the light absorbing layer 233 formed by a flow of germanium is equal to or more than 1.3 eV and is equal to or less than 1.7 eV, the deposition rate of the light absorbing layer 233 is prevented from being rapidly reduced and the dangling bond density and a recombination are reduced. Therefore, the efficiency is prevented from being degraded.

If an average germanium content of the light absorbing layer 233 formed by a flow of germanium is greater than 20 atomic %, the deposition rate of the light absorbing layer 233 is rapidly reduced and a recombination is increased by the increase of the dangling bond density. Consequently, the short-circuit current, the fill factor (FF) and the efficiency are reduced.

Meanwhile, when the light absorbing layer 233 is formed by a flow of oxygen, carbon or germanium, the average hydrogen content of the light absorbing layer 233 can be equal to or more than 15 atomic % and is equal to or less than 25 atomic %. If the average hydrogen content of the light absorbing layer 233 is less than 15 atomic %, the size and density of the quantum dot are reduced, and then the optical band gap of the light absorbing layer 233 can be reduced and the degradation rate of the light absorbing layer 233 can be increased. If the average hydrogen content of the light absorbing layer 233 is greater than 25 atomic %, the diameter of the crystalline silicon grain is excessively increased so that a volume of unstable amorphous silicon is also increased. Accordingly, the degradation rate can be increased.

Thus, the light absorbing layer 233 formed by a flow of germanium can be included in either a bottom cell of a double junction photovoltaic device including two photoelectric transformation layers 230 or a middle cell of a triple junction photovoltaic device including three photoelectric transformation layers 230. The bottom cell is adjacent to the top cell on which light is first incident among two photoelectric transformation layers 230. The middle cell is adjacent to the top cell on which light is first incident among three photoelectric transformation layers 230.

That is to say, since the optical hand gap of the light absorbing layer 233 formed by a flow of germanium is equal to or more than 1.3 eV and is equal to or less than 1.7 eV, and thus, is less than an optical band gap, which is equal to or more than 1.85 eV and equal to or less than 2.1 eV, of the light absorbing layer 233 used in the top cell. Accordingly, the light absorbing layer 233 formed by a flow of germanium can be used in either the bottom cell of the double junction photovoltaic device or the middle cell of the triple junction photovoltaic device including three photoelectric transformation layers 230.

While the first sub-layer 233A is formed first in the embodiments of the present invention, the second sub-layer 233B can be also formed before the first sub-layer 233A is formed.

A warming-up period WU can be provided before starting to deposit the light absorbing layer 233. In other words, as shown in FIGS. 5A to 7B, a voltage is not supplied to the electrode 340 of the chamber 310 during a period of time more than a first cycle P for supplying the non-silicon source gas, which includes non-silicon based element, with the first flow rate value α and the second flow rate value β. The period of time corresponds to the warming-up period.

Because a voltage is not supplied to the chamber during the warming-up period, plasma is not generated. Since the chamber 310 is in a vacuum state, a condition inside the chamber 310 may not satisfy the deposition condition of the light absorbing layer 233 even though source gas for forming the light absorbing layer 233 is supplied to the chamber.

Therefore, in the case where a deposition is not performed due to no generation of plasma during the warming-up period WU and where a deposition is performed by generation of plasma when a condition inside the chamber 310 satisfies the deposition condition of the light absorbing layer 233 after the warming-up period WU, the light absorbing layer 233 can be stably formed.

As shown in FIGS. 5B, 6B and 7B, the source gas including non-silicon based element such as germanium is supplied to the chamber such that the second flow rate value β is 0. Silane and hydrogen are uniformly supplied to the chamber. Here, if a hydrogen dilution ratio (that is, a ratio of the flow rate of silane to the flow rate of hydrogen) is large, crystallization of silicon is performed.

Accordingly, the second sub-layer 233B is made of hydrogenated micro-crystalline silicon (μc-Si:H) including a crystalline silicon grain. The first sub-layer 233A is made of hydrogenated micro-crystalline silicon germanium (μc-SiGe:H). As explained before, a light absorbing layer 233 according to this embodiment of the present invention may include a first area in which the first sub-layer 233A and second sub-layer 233B are alternately stacked and a second area other than the first area. Here, the second area may not have a structure in which the first sub-layer 233A and the second sub-layer 233B are alternately stacked and have a single layer. In this case, the second area may include hydrogenated micro-crystalline silicon, or a hydrogenated micro-crystalline silicon germanium which comprises relatively small amount of the germanium.

Since the first and the second sub-layers 233A and 233B have less optical band gaps than those of the sub-layers made of amorphous silicon germanium, the first and the second sub-layers 233A and 233B can easily absorb light with a longer wavelength. Accordingly, the light absorbing layer of the bottom cell of the double or triple junction photovoltaic device can include both the second sub-layer 233B including hydrogenated micro-crystalline silicon including a crystalline silicon grain and the first sub-layer 233A including hydrogenated micro-crystalline silicon germanium.

In order to absorb light with a long wavelength, an optical band gap of the light absorbing layer 233 made of hydrogenated micro-crystalline silicon germanium and hydrogenated micro-crystalline silicon can be equal to or more than 0.9 eV and equal to or less than 1.3 eV. An average germanium content of the light absorbing layer 233 can be is greater than 0 atomic % and equal to or less than 15 atomic %.

A thickness of the light absorbing layer 233 made of hydrogenated micro-crystalline silicon germanium and hydrogenated micro-crystalline silicon can be equal to or more than 0.5 μm and equal to or less than 1.0 μm. If the thickness of the, light absorbing layer 233 is less than 0.5 μm, the light absorbing layer 233 cannot perform its functions. If more than 1.0 μm, the thickness is so large that its efficiency is reduced.

A thickness of the second sub-layer 233B, which includes a crystalline silicon grain, made of hydrogenated micro-crystalline silicon can be equal to or more than 20 nm. If the thickness of the second sub-layer 23313 is less than 20 nm, it is difficult to form a crystalline silicon grain. Thus, it is hard to obtain the effect of the light absorbing layer 233 including the first and the second sub-layers 233A and 233B.

As described above, the thickness of the light absorbing layer 233 can be equal to or more than 0.5 μm and equal to or less than 1.0 μm. Also, a period of time equal to or more than 5 cycles P and equal to or less than 10 cycles P may be required in order that the light absorbing layer 233 including the first and the second sub-layers 233A and 23313 can fully perform its functions. Therefore, when germanium with the first flow rate value α and the second flow rate value β (equal to 0) is supplied to the chamber during one cycle P, a sum of the thickness of the first sub-layer 233A and the thickness of the sub-layer 233B can be equal to or more than 50 nm and equal to or less than 100 nm.

An average crystal volume fraction of the light absorbing layer 233 made of hydrogenated micro-crystalline silicon germanium and hydrogenated micro-crystalline silicon can be equal to or more than 30% and equal to or less than 60%. If the average crystal volume fraction is less than 30%, amorphous silicon is generated a lot and carriers are increasingly recombined with each other, thereby reducing the efficiency. If the average crystal volume fraction is more than 60%, a volume of grain boundary in a crystalline material is increased and a crystal defect is increased, thereby increasing the recombination of carriers.

An average oxygen content of the light absorbing layer 233 made of hydrogenated micro-crystalline silicon germanium and hydrogenated micro-crystalline silicon can be equal to or less than 1.0×10²⁰ atoms/cm³. If the average oxygen content of the light absorbing layer 233 is more than 1.0×10²⁰ atoms/cm³, conversion efficiency is reduced. While the first sub-layer 233A is formed first in the embodiment of the present invention, the second sub-layer 233B can be formed prior to the first sub-layer 233A.

Here, the thicknesses of the first and second sub-layers 233A and 233B and the absorbing layer 233 not be entirely uniform due to the uncertainty of the process conditions and parameters. A uniformity degree of each thickness of the first and second sub-layers 233A and 233B, and the absorbing layer 233 may be in a range that the deviation from the mean value of the each thickness is equal to or less than 10%. By maintaining the degree of thickness uniformity of each of the first and second sub-layers 233A and 233B, and the absorbing layer 233 in the above mentioned range, it is possible to prevent the properties of the light absorbing layer 233 from being deteriorated.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such limitation is not intended to be interpreted under 35 USC §112(6).

What is claimed is:

1. A photovoltaic device comprising:
a substrate;
a first electrode disposed on the substrate;
a photoelectric transformation layer disposed on the first electrode, the photoelectric transformation layer comprising a light absorbing layer which comprises at least one pair of an intrinsic first sub-layer and an intrinsic second sub-layer, each of which comprises a hydrogenated amorphous silicon based material and a hydrogenated proto-crystalline silicon based material having a crystalline silicon grain, and comprises a non-silicon based element; and
a second electrode disposed on the photoelectric transformation layer.

2. The photovoltaic device of claim 1, wherein the light absorbing layer is divided into a first area and a second area, the first area is constituted by the at least one pair of the first sub-layer and the second sub-layer, and the second area is constituted by a single layer.

3. The photovoltaic device of claim 1, wherein a diameter of the crystalline silicon grain is equal to or more than 3 nm and equal to or less than 10 nm.

4. The photovoltaic device of claim 1, wherein the non-silicon based element is oxygen or carbon, and an average oxygen content or an average carbon content of the light absorbing layer is greater than 0 atomic % and equal to or less than 3 atomic %.

5. The photovoltaic device of claim 1, wherein the non-silicon based element is germanium, and an average germanium content of the light absorbing layer is greater than 0 atomic % and equal to or less than 20 atomic %

6. The photovoltaic device of claim 1, wherein the non-silicon based element is oxygen or carbon, and an optical band gap of the light absorbing layer is equal to or more than 1.85 eV and is equal to or less than 2.1 eV.

7. The photovoltaic device of claim 1, wherein the non-silicon based element is germanium, and an optical band gap of the light absorbing layer is equal to or more than 1.3 eV and is equal to or less than 1.7 eV.

8. The photovoltaic device of claim 1, wherein the non-silicon based element is oxygen or carbon, and a thickness of the light absorbing layer is equal to or more than 150 nm and equal to or less than 300 nm.

9. The photovoltaic device of claim 1, wherein the non-silicon based element is germanium, and a thickness of the light absorbing layer is equal to or more than 300 nm and equal to or less than 1000 nm.

10. The photovoltaic device of claim 1, wherein the non-silicon based element is oxygen or carbon, and the photovoltaic device comprises a plurality of photoelectric transformation layers, and the light absorbing layer is included in the photoelectric transformation layer on which light is first incident among the plurality of photoelectric transformation layers.

11. The photovoltaic device of claim 1, wherein the non-silicon based element is germanium, and the photovoltaic device comprises a plurality of photoelectric transformation layers, and the light absorbing layer is included in the photoelectric transformation layer adjacent to a photoelectric transformation layer on which light is first incident among the plurality of photoelectric transformation layers.

12. The photovoltaic device of claim 1, wherein an average hydrogen content of the light absorbing layer is equal to or more than 15 atomic % and equal to or less than 25 atomic %.

13. A photovoltaic device comprising:
a substrate;
a first electrode disposed on the substrate;
a photoelectric transformation layer disposed on the first electrode, the photoelectric transformation layer comprising a light absorbing layer which comprises at least one pair of an intrinsic first sub-layer and an intrinsic second sub-layer, each of which comprises hydrogenated micro-crystalline silicon germanium and hydrogenated micro-crystalline silicon; and
a second electrode disposed on the photoelectric transformation layer.

14. The photovoltaic device of claim 13, wherein the light absorbing layer is divided into a first area and a second area, the first area is constituted by the at least one pair of the first sub-layer and the second sub-layer, and the second area is constituted by a single layer.

15. The photovoltaic device of claim 13, wherein an average hydrogen content of the light absorbing layer is equal to or more than 15 atomic % and equal to or less than 25 atomic %.

16. The photovoltaic device of claim 13, wherein an average germanium content of the light absorbing layer is greater than 0 atomic % and equal to or less than 15 atomic %.

17. The photovoltaic device of claim 13, wherein an average crystal volume fraction of the light absorbing layer is equal to or more than 30% and equal to or less than 60%.

18. The photovoltaic device of claim 13, wherein an optical band gap of the light absorbing layer is equal to or more than 0.9 eV and is equal to or less than 1.3 eV.

19. The photovoltaic device of claim 13, wherein a thickness of the light absorbing layer is equal to or more than 0.5 μm and equal to or less than 1.0 μm.

20. The photovoltaic device of claim 13, wherein a thickness of the second sub-layer is equal to or more than 20 nm.

21. The photovoltaic device of claim 13, wherein a sum of thicknesses of the first sub-layer and the second sub-layer in each of the pair is equal to or more than 50 nm and equal to or less than 100 nm.

22. The photovoltaic device of claim 13, wherein an average oxygen content of the light absorbing layer is equal to or less than 1.0×10²⁰ atoms/cm³.

23. The photovoltaic device of claim 13, wherein the photovoltaic device comprises a plurality of photoelectric transformation layers, and the light absorbing layer is included in the photoelectric transformation layer on which light is lastly incident among the plurality of photoelectric transformation layers.

24. The photovoltaic device of claim 1, wherein an uniformity degree of each thickness of the first sub-layer and the second sub-layer is in a range that a deviation from the mean value of the each thickness is equal to or less than 10%.

25. The photovoltaic device of claim 13, wherein an uniformity degree of each thickness of the first sub-layer and the second sub-layer is in a range that a deviation from the mean value of the each thickness is equal to or less than 10%.
